(19) United States
(12) Patent Application Publication
(10) Pub. No.: US 2007/0139121 A1
(43) Pub. Date: Jun. 21, 2007

(54) Amplifier symmetric supply regulation

(75) Inventors: David John Baldwin, Allen, TX (US); Russell Max Kinder, Plano, TX (US); Patrick Muggler, Dallas, TX (US); Roy Clifton Jones III, Plano, TX (US)

Correspondence Address: TEXAS INSTRUMENTS INCORPORATED, P O BOX 655474, M/S 3999, DALLAS, TX, 75265, US

(73) Assignee: Texas Instruments Incorporated

(21) Appl. No.: 11/314,563

(22) Filed: Dec. 21, 2005

(51) Int. Cl. H03F 3/04

(52) U.S. Cl. 330/297

(57) ABSTRACT

A power converter receiving a single-sided supply which is ground-terminated and providing a positive supply and a regulated negative supply that is optimized to the expected output range of a class AB amplifier, as well as providing a symmetric positive supply having excellent efficiency. The converter finds application as a compact converter to power an audio amplifier driving an audio device which is ground terminated, such as a speaker.

### FIELD OF THE INVENTION

The present invention pertains to headphone amplifiers, and more particularly to amplifiers translating an audio signal from a single-sided supply to a device which is ground-terminated.

### BACKGROUND OF THE INVENTION

There are two conventional methods to translate an audio signal from a single-sided power supply to a device which is ground terminated. The first is to use a DC blocking cap to AC couple the audio signal to the device, such as a speaker, without allowing the common-mode bias voltage (usually half the supply in a single-sided supply system) to result in a DC current. This solves the DC current issue, but the sharp level change from 0 volts to half supply on power-up results in a loud audible pop. Elaborate circuitry is required to charge the blocking cap sub-sonically, resulting in larger die area, and long startup times (0.5 second typical) Also, the blocking cap itself is quite large (470 uF typical), which is physically unreasonable for small handheld devices.

The second method is to level-shift the output signal so that it is ground-referenced. This approach has the advantage that the output is always ground-referenced, so the issues with power-up pop are reduced. Also, no DC blocking cap is needed. The disadvantage with this approach is that a negative power supply must be created via a type of power converter, either a capacitive (i.e. charge pump) or switched mode power supply (i.e. flyback regulator). Usually, the charge pump is employed, which provides the audio amplifier 2*Vsupply. For a given a requirement, such as a 1.6V output signal (peak), the resulting 2*Vsupply is much greater than necessary for headroom, and a class AB amplifier output efficiency suffers.

Regulating the charge pump voltage to a lower negative value will yield higher efficiency for the class AB amplifier stage, but at a corresponding reduction in pump efficiency. Even then, the Class AB amplifier efficiency improvement is only for the negative output swings, since the supplies are asymmetrical. Frequency modulation methods for charge pump regulation are also fraught with other undesirable traits, such as increased negative supply ripple at lighter load, and the possibility of operation in the audio band which is not feasible.

### SUMMARY OF INVENTION

The present invention achieves technical advantages as a power converter receiving a single-sided supply which is ground-terminated and providing a positive supply and a regulated negative supply that is optimized to the expected output range of a class AB amplifier, as well as providing a symmetric positive supply having excellent efficiency. The converter finds application as a compact converter to power an audio amplifier driving an audio device which is ground terminated, such as a speaker.

### BRIEF DESCRIPTION OF THE DRAWINGS

FIG. 1 is a schematic diagram of an improved SMPS circuit according to a preferred embodiment of the present invention;

FIG. 2 depicts the first phase of current conduction through the circuit of FIG. 1;

FIG. 3 depicts the second phase of current conduction through the circuit of FIG. 1;

FIG. 4 depicts the third phase of current conduction through the circuit of FIG. 1; and

FIG. 5 depicts the fourth phase of current conduction through the circuit of FIG. 1.

### DETAILED DESCRIPTION OF THE PRESENT INVENTION

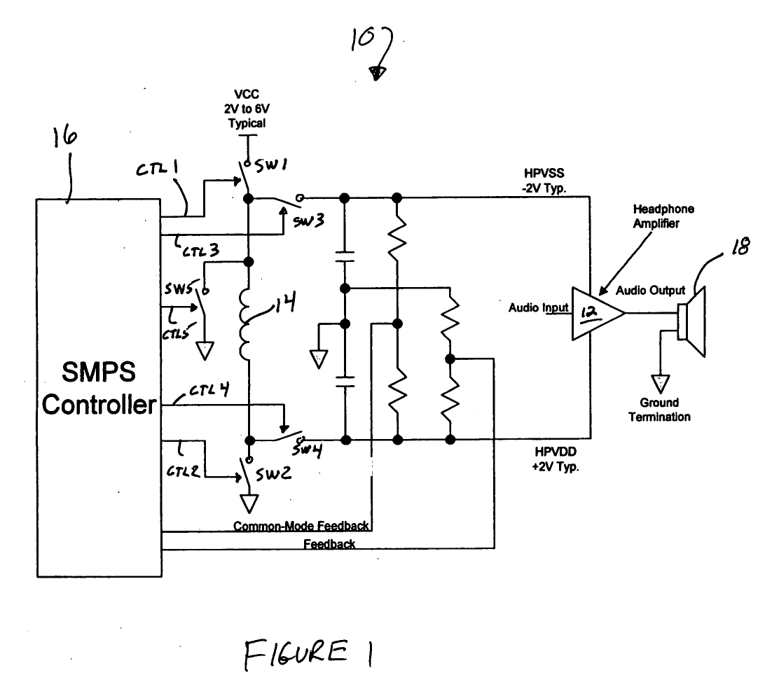

Referring to FIG. 1, there is shown an improved SMPS circuit 10 configured to provide a regulated negative supply that is optimized to the expected output range of a class AB amplifier 12, as well as to provide a symmetric positive supply with an improved efficiency, which can exceed 90% efficiency.

A magnetic component, seen to comprise of an inductor 14, is provided in the circuit 10 which component 14 is now advantageously available in a compact, surface mounted form factor which renders this circuit 10 ideal for use as a head phone amplifier. Circuit 10 has a plurality of switches SW1-SW5 each selectively controlled by SMPS controller 16 via respective control lines CTL1-CTL5, and is configured to translate an audio signal from a single-sided supply VCC to an audio device, such as a speaker 18, which is ground terminated.

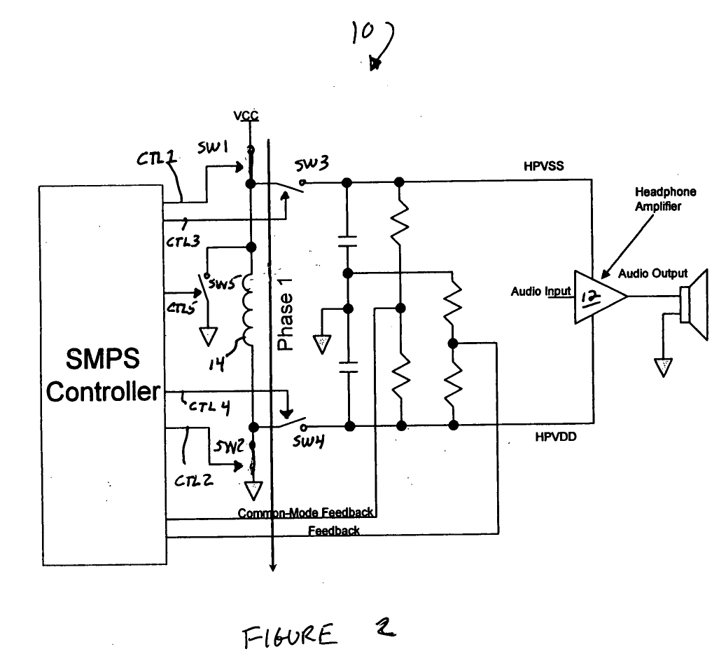

Referring to FIG. 2, there is shown the circuit 10 having the respective switches SW1-SW5 configured by SMPS controller 16 in a first configuration to conduct current from a single-sided voltage source VCC through inductor 14 to ground.

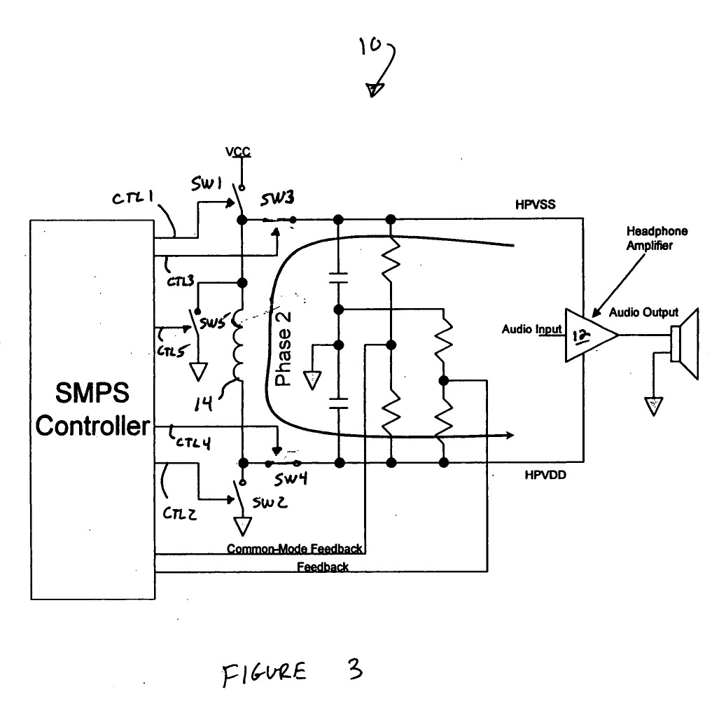

Referring now to FIG. 3, there is shown circuit 10 having switches SW1-SW5 configured in a second configuration to conduct current from the positive supply HPVDD of the amplifier through the inductor 14 to the negative supply HPVSS.

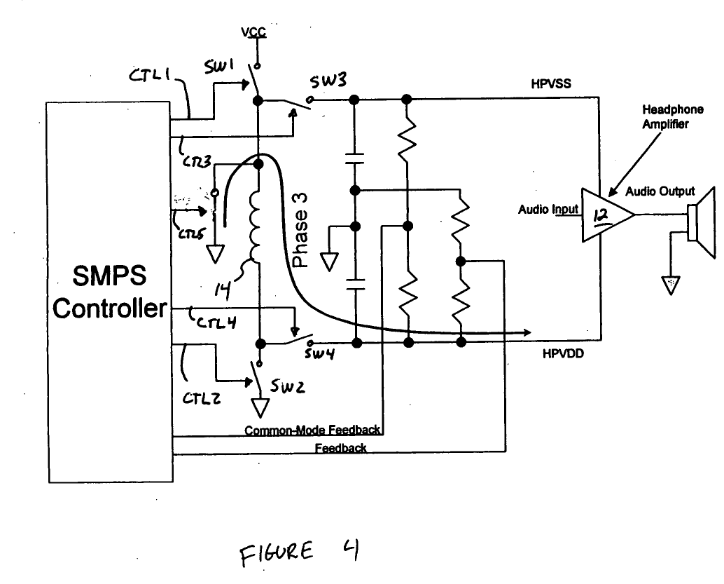

FIG. 4 depicts the circuit 10 with the switches SW1-SW5 configured in a third configuration to conduct current from ground through the inductor 14 to the negative supply HPVSS.

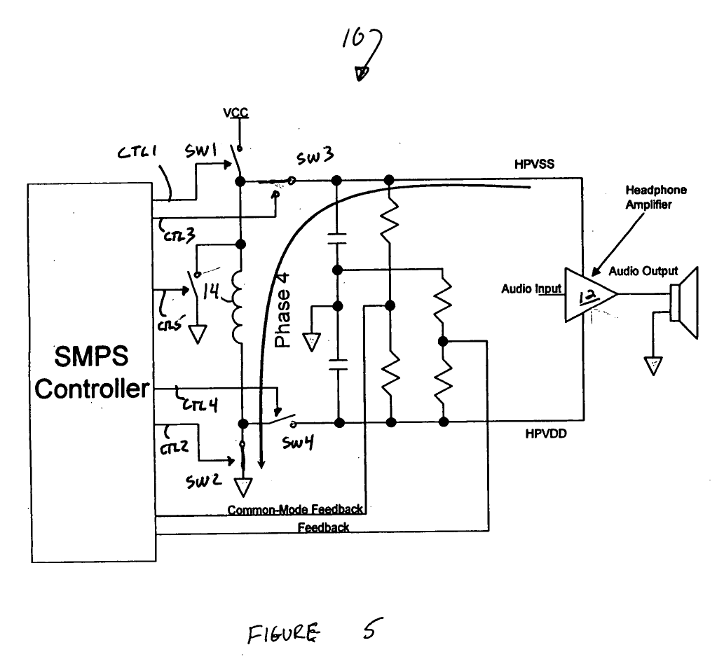

FIG. 5 depicts the circuit 10 with the switches SW1-SW5 configured in a fourth state configuration to conduct current from the positive supply HPVDD to ground.

Though the invention has been described with respect to a specific preferred embodiment, many variations and modifications will become apparent to those skilled in the art upon reading the present application. It is therefore the intention that the appended claims be interpreted as broadly as possible in view of the prior art to include all such variations and modifications.

What is claimed is:

1. A circuit, comprising:
a control circuit configured to receive a single-sided power supply and power a class AB amplifier translating an audio signal from a single-sided power supply to an audio device which is ground terminated, the control circuit configured to provide both a positive power supply and a negative power supply, the control circuit configured to provide a regulated said negative power supply that is optimized to the output range of the class AB amplifier.

2. The circuit as specified in claim 1 wherein the control circuit is configured to provide a symmetric said positive power supply having at least a 97% efficiency.

3. The circuit as specified in claim 2 wherein the control circuit comprises at least one inductor.

4. The circuit as specified in claim 3 wherein the inductor is surface mounted inductor.
